(19) United States
(12) Patent Application Publication
(10) Pub. No.: US 2023/0011756 A1
(43) Pub. Date: Jan. 12, 2023

(54) HIGH DENSITY CAPACITOR AND METHOD OF MAKING THE SAME

(71) Applicant: Taiwan Semiconductor Manufacturing Company Limited, Hsinchu (TW)

(72) Inventors: Cheng-Yi WU, Taichung City (TW); Katherine H. CHIANG, New Taipei City (TW); Chung-Te LIN, Tainan City (TW); Hsin-Yu LAI, Hsinchu (TW); Yun-Feng KAO, Hsinchu (TW)

(21) Appl. No.: 17/691,233

(22) Filed: Mar. 10, 2022

Related U.S. Application Data
(60) Provisional application No. 63/220,419, filed on Jul. 9, 2021.

(51) Int. Cl. H01L 27/08; H01L 27/06; H01G 4/005; H01L 49/02; H01L 23/522

(52) U.S. Cl. CPC H01L 27/0805; H01L 27/0688; H01G 4/005; H01L 28/91; H01L 23/5226; H01G 4/40

(57) ABSTRACT

A disclosed high-density capacitor includes a top electrode having an electrically conducting material forming a three-dimensional structure. The three-dimensional structure includes a plurality of vertical portions extending in a vertical direction and horizontal portions, that are interleaved within the vertical portions and extend in a first horizontal direction. The high-density capacitor further includes a dielectric layer formed over the top electrode, and a bottom electrode including an electrically conducting material, such that the bottom electrode is separated from the top electrode by the dielectric layer. Further, the bottom electrode envelopes some of the plurality of vertical portions of the top electrode. The disclosed high-density capacitor further includes a plurality of support structures that are aligned with the first horizontal direction such that the horizontal portions of the top electrode are formed under respective support structures. The high-density capacitor has a capacitance that is proportional to the volume of the capacitor.

### RELATED APPLICATION

This application claims priority to U.S. Provisional Patent Application No. 63/220,419 entitled “High Density Vertical Plates Capacitor” filed on Jul. 9, 2021, the entire contents of which are hereby incorporated by reference for all purposes.

### BACKGROUND

The semiconductor industry has grown due to continuous improvements in integration density of various electronic components (e.g., transistors, diodes, resistors, inductors, capacitors, etc.). For the most part, these improvements in integration density have come from successive reductions in minimum feature size, which allow more components to be integrated into a given area. In this regard, individual transistors, interconnects, and related structures have become increasingly smaller and there is an ongoing need to develop new materials, processes, and designs of semiconductor devices and interconnects to allow further progress.

Thin film transistors (TFT) made of oxide semiconductors are an attractive option for back-end-of-line (BEOL) integration since TFTs may be processed at low temperatures and thus, will not damage previously fabricated devices. For example, the fabrication conditions and techniques may not damage previously fabricated front-end-of-line (FEOL) and middle end-of-line (MEOL) devices. Circuits based on TFT devices may further include other components that may be fabricated in a BEOL process, such as capacitors, inductors, resistors, and integrated passive devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first exemplary structure after formation of complementary metal-oxide-semiconductor (CMOS) transistors, first metal interconnect structures formed in lower-level dielectric material layers, and an isolation dielectric layer according to an embodiment of the present disclosure.

FIG. 2 is a vertical cross-sectional view of an intermediate structure used in the formation of a high-density capacitor, according to various embodiments.

FIG. 3A is a plan view of a further intermediate structure used in the formation of a high-density capacitor, according to various embodiments.

FIG. 3B is a first vertical cross-sectional view of the intermediate structure of FIG. 3A along line B-B, according to various embodiments.

FIG. 3C is a second vertical cross-sectional view of the intermediate structure of FIG. 3A along line C-C, according to various embodiments.

FIG. 4A is a plan view of a further intermediate structure used in the formation of a high-density capacitor, according to various embodiments.

FIG. 4B is a first vertical cross-sectional view of the intermediate structure of FIG. 4A along line B-B, according to various embodiments.

FIG. 4C is a second vertical cross-sectional view of the intermediate structure of FIG. 4A along line C-C, according to various embodiments.

FIG. 5A is a plan view of a further intermediate structure used in the formation of a high-density capacitor, according to various embodiments.

FIG. 5B is a first vertical cross-sectional view of the intermediate structure of FIG. 5A along line B-B, according to various embodiments.

FIG. 5C is a second vertical cross-sectional view of the intermediate structure of FIG. 5A along line C-C, according to various embodiments.

FIG. 5D is a third vertical cross-sectional view of the intermediate structure of FIG. 5A along line D-D, according to various embodiments.

FIG. 5E is a fourth vertical cross-sectional view of the intermediate structure of FIG. 5A along line E-E, according to various embodiments.

FIG. 6A is a plan view of a further intermediate structure used in the formation of a high-density capacitor, according to various embodiments.

FIG. 6B is a first vertical cross-sectional view of the intermediate structure of FIG. 6A along line B-B, according to various embodiments.

FIG. 6C is a second vertical cross-sectional view of the intermediate structure of FIG. 6A along line C-C, according to various embodiments.

FIG. 6D is a third vertical cross-sectional view of the intermediate structure of FIG. 6A along line D-D, according to various embodiments.

FIG. 6E is a fourth vertical cross-sectional view of the intermediate structure of FIG. 6A along line E-E, according to various embodiments.

FIG. 7A is a plan view of a further intermediate structure used in the formation of a high-density capacitor, according to various embodiments.

FIG. 7B is a first vertical cross-sectional view of the intermediate structure of FIG. 7A along line B-B, according to various embodiments.

FIG. 7C is a second vertical cross-sectional view of the intermediate structure of FIG. 7A along line C-C, according to various embodiments.

FIG. 7D is a third vertical cross-sectional view of the intermediate structure of FIG. 7A along line D-D, according to various embodiments.

FIG. 7E is a fourth vertical cross-sectional view of the intermediate structure of FIG. 7A along line E-E, according to various embodiments.

FIG. 8A is a plan view of a further intermediate structure used in the formation of a high-density capacitor, according to various embodiments.

FIG. 8B is a first vertical cross-sectional view of the intermediate structure of FIG. 8A along line B-B, according to various embodiments.

FIG. 8C is a second vertical cross-sectional view of the intermediate structure of FIG. 8A along line C-C, according to various embodiments.

FIG. 8D is a third vertical cross-sectional view of the intermediate structure of FIG. 8A along line D-D, according to various embodiments.

FIG. 8E is a fourth vertical cross-sectional view of the intermediate structure of FIG. 8A along line E-E, according to various embodiments.

FIG. 9A is a plan view of a further intermediate structure used in the formation of a high-density capacitor, according to various embodiments.

FIG. 9B is a first vertical cross-sectional view of the intermediate structure of FIG. 9A along line B-B, according to various embodiments.

FIG. 9C is a second vertical cross-sectional view of the intermediate structure of FIG. 9A along line C-C, according to various embodiments.

FIG. 9D is a third vertical cross-sectional view of the intermediate structure of FIG. 9A along line D-D, according to various embodiments.

FIG. 9E is a fourth vertical cross-sectional view of the intermediate structure of FIG. 9A along line E-E, according to various embodiments.

FIG. 10A is a plan view of a further intermediate structure used in the formation of a high-density capacitor, according to various embodiments.

FIG. 10B is a first vertical cross-sectional view of the intermediate structure of FIG. 10A along line B-B, according to various embodiments.

FIG. 10C is a second vertical cross-sectional view of the intermediate structure of FIG. 10A along line C-C, according to various embodiments.

FIG. 10D is a third vertical cross-sectional view of the intermediate structure of FIG. 10A along line D-D, according to various embodiments.

FIG. 10E is a fourth vertical cross-sectional view of the intermediate structure of FIG. 10A along line E-E, according to various embodiments.

FIG. 11A is a plan view of a further intermediate structure used in the formation of a high-density capacitor, according to various embodiments.

FIG. 11B is a first vertical cross-sectional view of the intermediate structure of FIG. 11A along line B-B, according to various embodiments.

FIG. 11C is a second vertical cross-sectional view of the intermediate structure of FIG. 11A along line C-C, according to various embodiments.

FIG. 11D is a third vertical cross-sectional view of the intermediate structure of FIG. 11A along line D-D, according to various embodiments.

FIG. 11E is a fourth vertical cross-sectional view of the intermediate structure of FIG. 11A along line E-E, according to various embodiments.

FIG. 12A is a plan view of a high-density capacitor, according to various embodiments.

FIG. 12B is a first vertical cross-sectional view of the high-density capacitor of FIG. 12A along line B-B, according to various embodiments.

FIG. 12C is a second vertical cross-sectional view of the high-density capacitor of FIG. 12A along line C-C, according to various embodiments.

FIG. 12D is a third vertical cross-sectional view of the high-density capacitor of FIG. 12A along line D-D, according to various embodiments.

FIG. 12E is a fourth vertical cross-sectional view of the high-density capacitor of FIG. 12A along line E-E, according to various embodiments.

FIG. 13 is a flowchart illustrating operations of a method of fabricating a high-density capacitor, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

According to various embodiments of the present disclosure, a high-density capacitor is provided that may be formed in a BEOL process and may be incorporated with other BEOL circuit components such as TFT devices. As such, the disclosed high-density capacitor may include materials that may be processed at low temperatures and thus, may not damage previously fabricated devices (e.g., FEOL and MEOL devices).

The disclosed high-density capacitor may include a top electrode having a first electrically conducting material and forming a three-dimensional structure. The three-dimensional structure may include a plurality of vertical portions extending in a vertical direction and horizontal portions, such that the horizontal portions may be interleaved within the vertical portions and extend in a first horizontal direction. The high-density capacitor may further include a dielectric layer formed over the top electrode, and a bottom electrode including a second electrically conducting material, such that the bottom electrode is separated from the top electrode by the dielectric layer. Further, the bottom electrode may be configured to envelope some of the plurality of vertical portions of the top electrode. The bottom electrode may have the second electrically conducting material formed as a plurality of three-dimensional structures separated from one another in a horizontal plan, with each three-dimensional structure having four vertical walls and one horizontal bottom wall. The top electrode includes the first electrically conducting material surrounding the bottom electrode. The first electrically conducting material may be the same or different material as the second electrically conducting material.

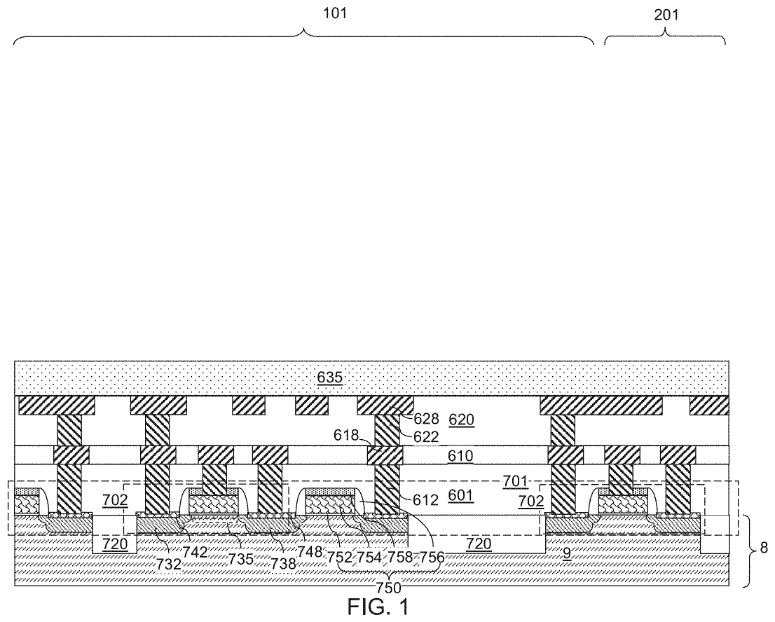

Referring to FIG. 1, a first exemplary structure according to a first embodiment of the present disclosure is illustrated. The first exemplary structure includes a substrate 8, which may be a semiconductor substrate such as a commercially available silicon substrate. The substrate 8 may include a semiconductor material layer 9 at least at an upper portion thereof. The semiconductor material layer 9 may be a surface portion of a bulk semiconductor substrate, or may be a top semiconductor layer of a semiconductor-on-insulator (SOI) substrate. In one embodiment, the semiconductor material layer 9 includes a single crystalline semiconductor material such as single crystalline silicon. In one embodiment, the substrate 8 may include a single crystalline silicon substrate including a single crystalline silicon material.

Shallow trench isolation structures 720 including a dielectric material such as silicon oxide may be formed in an upper portion of the semiconductor material layer 9. Suitable doped semiconductor wells, such as p-type wells and n-type wells, may be formed within each area that is laterally enclosed by a portion of the shallow trench isolation structures 720. Field effect transistors 702 may be formed over the top surface of the semiconductor material layer 9. For example, each field effect transistor 702 may include a source electrode 732, a drain electrode 738, a semiconductor channel 735 that includes a surface portion of the substrate 8 extending between the source electrode 732 and the drain electrode 738, and a gate structure 750. The semiconductor channel 735 may include a single crystalline semiconductor material. Each gate structure 750 may include a gate dielectric layer 752, a gate electrode 754, a gate cap dielectric 758, and a dielectric gate spacer 756. A source-side metal-semiconductor alloy region 742 may be formed on each source electrode 732, and a drain-side metal-semiconductor alloy region 748 may be formed on each drain electrode 738.

The first exemplary structure may include a memory array region 101 in which an array of ferroelectric memory cells may be subsequently formed. The first exemplary structure may further include a peripheral region 201 in which metal wiring for the array of ferroelectric memory devices is provided. Generally, the field effect transistors 702 in the CMOS circuitry 701 may be electrically connected to an electrode of a respective ferroelectric memory cell by a respective set of metal interconnect structures.

Devices (such as field effect transistors 702) in the peripheral region 200 may provide functions that operate the array of ferroelectric memory cells to be subsequently formed. Specifically, devices in the peripheral region may be configured to control the programming operation, the erase operation, and the sensing (read) operation of the array of ferroelectric memory cells. For example, the devices in the peripheral region may include a sensing circuitry and/or a programming circuitry. The devices formed on the top surface of the semiconductor material layer 9 may include complementary metal-oxide-semiconductor (CMOS) transistors and optionally additional semiconductor devices (such as resistors, diodes, capacitors, etc.), and are collectively referred to as CMOS circuitry 701.

One or more of the field effect transistors 702 in the CMOS circuitry 701 may include a semiconductor channel 735 that contains a portion of the semiconductor material layer 9 in the substrate 8. If the semiconductor material layer 9 includes a single crystalline semiconductor material such as single crystalline silicon, the semiconductor channel 735 of each field effect transistor 702 in the CMOS circuitry 701 may include a single crystalline semiconductor channel such as a single crystalline silicon channel. In one embodiment, a plurality of field effect transistors 702 in the CMOS circuitry 701 may include a respective node that is subsequently electrically connected to a node of a respective ferroelectric memory cell to be subsequently formed. For example, a plurality of field effect transistors 702 in the CMOS circuitry 701 may include a respective source electrode 732 or a respective drain electrode 738 that is subsequently electrically connected to a node of a respective ferroelectric memory cell to be subsequently formed.

In one embodiment, the CMOS circuitry 701 may include a programming control circuit configured to control gate voltages of a set of field effect transistors 702 that are used for programming a respective ferroelectric memory cell and to control gate voltages of thin film transistors to be subsequently formed. In this embodiment, the programming control circuit may be configured to provide a first programming pulse that programs a respective ferroelectric dielectric material layer in a selected ferroelectric memory cell into a first polarization state in which electrical polarization in the ferroelectric dielectric material layer points toward a first electrode of the selected ferroelectric memory cell, and to provide a second programming pulse that programs the ferroelectric dielectric material layer in the selected ferroelectric memory cell into a second polarization state in which the electrical polarization in the ferroelectric dielectric material layer points toward a second electrode of the selected ferroelectric memory cell.

In one embodiment, the substrate 8 may include a single crystalline silicon substrate, and the field effect transistors 702 may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

According to an aspect of the present disclosure, the field effect transistors 702 may be subsequently electrically connected to drain electrodes and gate electrodes of access transistors including semiconducting metal oxide plates to be formed above the field effect transistors 702. In one embodiment, a subset of the field effect transistors 702 may be subsequently electrically connected to at least one of the drain electrodes and the gate electrodes. For example, the field effect transistors 702 may include first word line drivers configured to apply a first gate voltage to first word lines through a first subset of lower-level metal interconnect structures to be subsequently formed, and second word line drivers configured to apply a second gate voltage to second word lines through a second subset of the lower-level metal interconnect structures. Further, the field effect transistors 702 may include bit line drivers configured to apply a bit line bias voltage to bit lines to be subsequently formed, and sense amplifiers configured to detect electrical current that flows through the bit lines during a read operation.

Various metal interconnect structures formed within dielectric material layers may be subsequently formed over the substrate 8 and the semiconductor devices thereupon (such as field effect transistors 702). In an illustrative example, the dielectric material layers may include, for example, a first dielectric material layer 601 that may be a layer that surrounds the contact structure connected to the source and drains (sometimes referred to as a contact-level dielectric material layer 601), a first interconnect-level dielectric material layer 610, and a second interconnect-level dielectric material layer 620. The metal interconnect structures may include device contact via structures 612 formed in the first dielectric material layer 601 and contact a respective component of the CMOS circuitry 701, first metal line structures 618 formed in the first interconnect-level dielectric material layer 610, first metal via structures 622 formed in a lower portion of the second interconnect-level dielectric material layer 620, and second metal line structures 628 formed in an upper portion of the second interconnect-level dielectric material layer 620.

Each of the dielectric material layers (601, 610, 620) may include a dielectric material such as undoped silicate glass, a doped silicate glass, organosilicate glass, amorphous fluorinated carbon, porous variants thereof, or combinations thereof. Each of the metal interconnect structures (612, 618, 622, 628) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 622 and the second metal line structures 628 may be formed as integrated line and via structures by a dual damascene process. The dielectric material layers (601, 610, 620) are herein referred to as lower-lower-level dielectric material layers. The metal interconnect structures (612, 618, 622, 628) formed within in the lower-level dielectric material layers are herein referred to as lower-level metal interconnect structures.

While the present disclosure is described using an embodiment in which an array of memory cells may be formed over the second line-and-via-level dielectric material layer 620, embodiments are expressly contemplated herein in which the array of memory cells may be formed at a different metal interconnect level.

An array of thin film transistors and an array of ferroelectric memory cells may be subsequently deposited over the dielectric material layers (601, 610, 620) that have formed therein the metal interconnect structures (612, 618, 622, 628). The set of all dielectric material layer that are formed prior to formation of an array of thin film transistors or an array of ferroelectric memory cells is collectively referred to as lower-level dielectric material layers (601, 610, 620). The set of all metal interconnect structures that is formed within the lower-level dielectric material layers (601, 610, 620) is herein referred to as first metal interconnect structures (612, 618, 622, 628). Generally, first metal interconnect structures (612, 618, 622, 628) formed within at least one lower-level dielectric material layer (601, 610, 620) may be formed over the semiconductor material layer 9 that is located in the substrate 8.

According to an aspect of the present disclosure, thin film transistors (TFTs) may be subsequently formed in a metal interconnect level that overlies that metal interconnect levels that contain the lower-level dielectric material layers (601, 610, 620) and the first metal interconnect structures (612, 618, 622, 628). In one embodiment, a planar dielectric material layer having a uniform thickness may be formed over the lower-level dielectric material layers (601, 610, 620). The planar dielectric material layer is herein referred to as an insulating matrix layer 635. The insulating matrix layer 635 includes a dielectric material such as undoped silicate glass, a doped silicate glass, organosilicate glass, or a porous dielectric material, and may be deposited by chemical vapor deposition. The thickness of the insulating matrix layer 635 may be in a range from 20 nm to 300 nm, although lesser and greater thicknesses may also be used.

Generally, interconnect-level dielectric layers (such as the lower-level dielectric material layer (601, 610, 620)) containing therein the metal interconnect structures (such as the first metal interconnect structures (612, 618, 622, 628)) may be formed over semiconductor devices. The insulating matrix layer 635 may be formed over the interconnect-level dielectric layers.

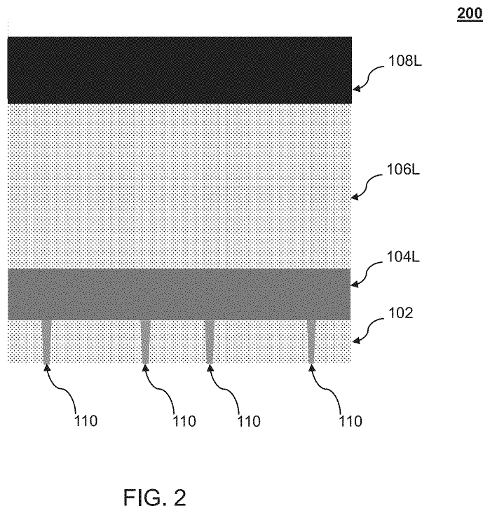

FIG. 2 is a vertical cross-sectional view of an intermediate structure 200 used in the formation of a high-density capacitor, according to various embodiments. The intermediate structure 200 may include a substrate 102, a lower-level etch-stop layer 104L, a dielectric layer 106L, and an upper-level etch stop layer 108L. The lower-level etch-stop layer 104L, the dielectric layer 106L, and the upper-level etch stop layer 108L may be formed as planar blanket (i.e., un-patterned) layers each having a respective planar top surface and a respective planar bottom surface.

The intermediate structure 200 may be formed in a BEOL process. As such, the substrate 102 may be a dielectric layer (e.g., an inter-layer dielectric or insulating matrix layer 635 from FIG. 1) that may embed one or more conductive structures 110. The one or more conductive structures 110 may be electrically connected to various interconnect structures (e.g., first metal interconnect structures (612, 618, 622, 628) in FIG. 1) formed below the substrate 102. Each of the one or more metallic structure 110 may include at least one conductive material, which may be a combination of a metallic liner layer (such as a metallic nitride or a metallic carbide) and a metallic fill material. Each metallic liner layer may include TiN, TaN, WN, TiC, TaC, and WC, and each metallic fill material portion may include W, Cu, Al, Co, Ru, Mo, Ta, Ti, alloys thereof, and/or combinations thereof. Other suitable materials within the contemplated scope of disclosure may also be used.

Each of the substrate 102 and the dielectric layer 106L may include, for example, undoped silicate glass, a doped silicate glass (e.g., deposited by decomposition of tetraethylorthosilicate (TEOS)), organosilicate glass, silicon oxynitride, or silicon carbide nitride. Other dielectric materials are within the contemplated scope of disclosure. The dielectric material of the substrate 102 and the dielectric layer 106L may be deposited by a conformal deposition process (such as a chemical vapor deposition process) or a self-planarizing deposition process (such as spin coating). The thickness of the substrate 102 and/or the dielectric layer 106L may each be in a range from approximately 15 nm to approximately 60 nm, such as from approximately 20 nm to approximately 40 nm, although smaller and larger thicknesses may also be used.

The lower-level etch-stop layer 104L and the upper-level etch-stop layer 108L may include an etch stop material such as silicon nitride, silicon carbide, silicon nitride carbide, or a dielectric metal oxide (such as aluminum oxide, titanium oxide, tantalum oxide, etc.). The lower-level etch-stop layer 104L and the upper-level etch-stop layer 108L may be deposited by a conformal or non-conformal deposition process. In one embodiment, the lower-level etch-stop layer 104L and the upper-level etch-stop layer 108L may be deposited by chemical vapor deposition, atomic layer deposition, or physical vapor deposition. The thickness of the lower-level etch-stop layer 104L and the upper-level etch-stop layer 108L may each be in a range from approximately 2 nm to approximately 20 nm, such as from approximately 3 nm to approximately 12 nm, although smaller and larger thicknesses may also be used.

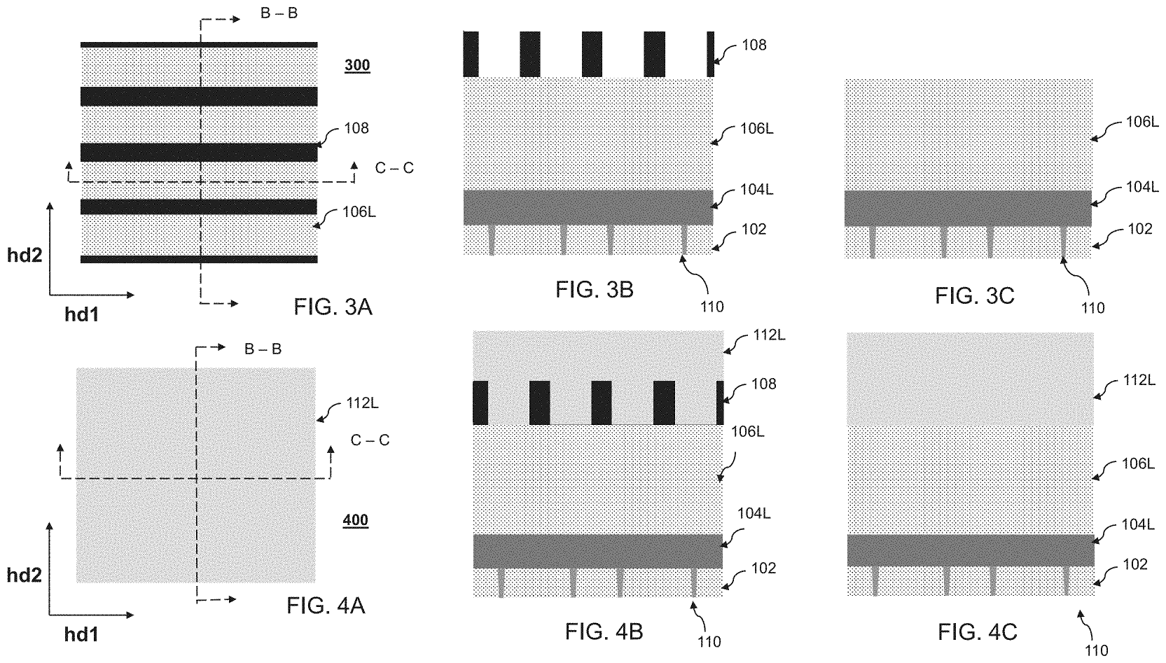

FIG. 3A is a plan view of a further intermediate structure 300 used in the formation of a high-density capacitor, according to various embodiments. FIG. 3A is a horizontal cross-sectional view defined by a horizontal plane that spans a first horizontal direction (hd1) and a second horizontal direction (hd2). FIGS. 3B and 3C show first and second vertical cross-sectional views of the intermediate structure 300 of FIG. 3A along lines B-B and C-C, respectively, according to various embodiments. In this regard, the vertical cross-section along line B-B of FIG. 3A is illustrated in FIG. 3B and the vertical cross-section along line C-C of FIG. 3A is shown in FIG. 3C. The intermediate structure 300 may be formed by patterning the upper-level etch-stop layer 108L (e.g., see FIG. 1) to form the patterned upper-level etch-stop structure 108. In this regard, a photoresist (not shown) may be formed over the top surface of the upper-level etch-stop layer 108L shown in FIG. 1. The photoresist may then be patterned using photolithographic techniques to form a patterned photoresist.

The patterned photoresist may then be used as a mask while patterning the upper-level etch-stop layer 108L. Patterning of the upper-level etch-stop layer 108L may be performed by using an anisotropic etch process. After etching, any residual photoresist may be removed by ashing or dissolution with a solvent. The resulting patterned upper-level etch-stop structure 108 is shown in FIGS. 3A and 3B, and includes a plurality of separate first extended structures, which may serve as an etch mask for patterning the dielectric layer 106L in further processing steps, as described in greater detail below. FIG. 3B is a view along a lengthwise direction (i.e., direction hd1 extends into the plane of FIG. 3B) of the first extended structures of the patterned upper-level etch-stop structure 108. FIG. 3C is a view along a width direction (i.e., direction hd2 extends into the plane of FIG. 3C) of the first extended structures of the patterned upper-level etch-stop structure 108 such that the cross-sectional view of FIG. 3C is taken between two adjacent first extended structures of the patterned upper-level etch-stop structure 108.

FIG. 4A is a plan view of a further intermediate structure 400 used in the formation of a high-density capacitor, according to various embodiments. FIGS. 4B and 4C show first and second vertical cross-sectional views of the intermediate structure 300 of FIG. 4A along lines B-B and C-C, respectively, according to various embodiments. In this regard, the vertical cross-section along line B-B of FIG. 4A is illustrated in FIG. 4B and the vertical cross-section along line C-C of FIG. 4A is shown in FIG. 4C. The structure 400 is generated by forming a hard mask layer 112L over the intermediate structure 300 of FIGS. 3A-3C.

The hard mask layer 112L may be made of any suitable material, such as amorphous carbon, amorphous hydrogenated carbon, organo siloxane based materials, SiN, SiON or combinations thereof. Other suitable materials are within the contemplated scope of disclosure. The hard mask layer 112L may be formed as a planar blanket (i.e., un-patterned) layer having a planar top surface and a planar bottom surface, and may be formed using chemical vapor deposition, physical vapor deposition, atomic layer deposition or any other suitable process.

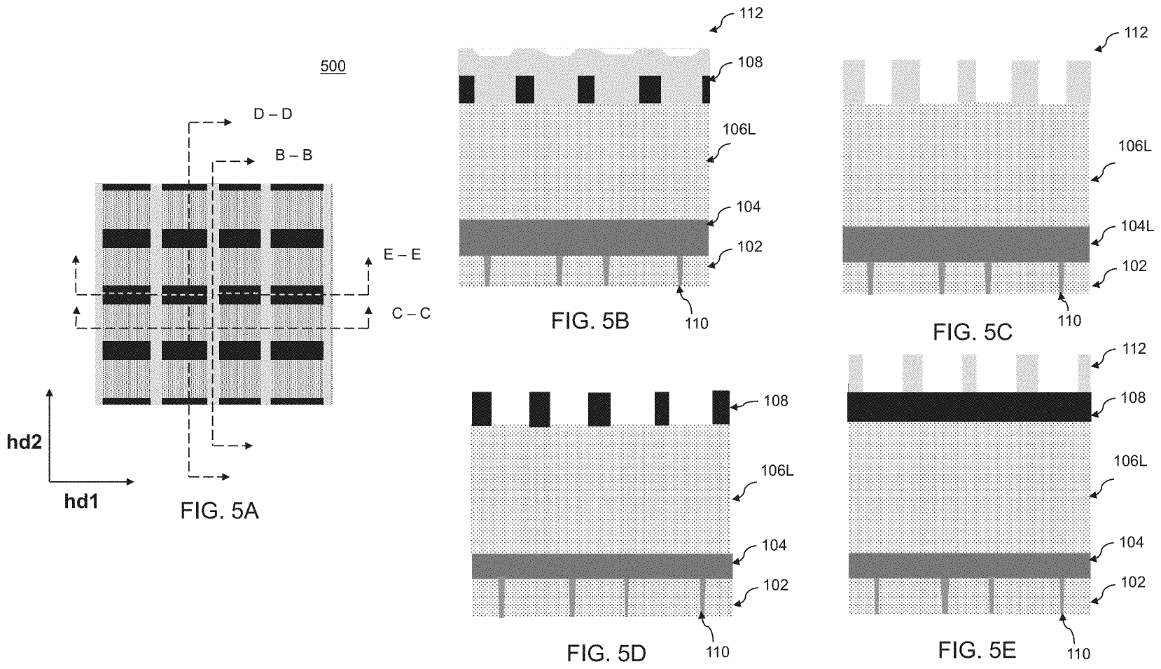

FIG. 5A is a plan view of a further intermediate structure 500 used in the formation of a high-density capacitor, according to various embodiments. FIGS. 5B, 5C, 5D, and 5E respectively show first, second, third, and fourth vertical cross-sectional views of the intermediate structure 500 of FIG. 5A, according to various embodiments. In this regard, the vertical cross-section along line B-B of FIG. 5A is illustrated in FIG. 5B, the vertical cross-section along line C-C of FIG. 5A is shown in FIG. 5C, the vertical cross-section along line D-D of FIG. 5A is illustrated in FIG. 5D, and the vertical cross-section along line E-E of FIG. 5A is shown in FIG. 5E.

The intermediate structure 500 may be formed by patterning the hard mask layer 112L (e.g., see FIGS. 4A to 4C) to form the patterned hard mask layer 112. In this regard, a photoresist (not shown) may be formed over the top surface of the hard mask layer 112L shown in FIGS. 4A to 4C. The photoresist may then be patterned using photolithographic techniques to form a patterned photoresist. The patterned photoresist may then be used as a mask while patterning the hard mask layer 112L. Patterning of hard mask layer 112L may be performed by using an anisotropic etch process. After etching, any residual photoresist may be removed by ashing or dissolution with a solvent.

The resulting patterned hard mask layer 112 is shown in FIGS. 5B, 5C, and 5E, and includes a plurality of separate second extended structures, which may serve as an etch mask for patterning the dielectric layer 106L in further processing steps, as described in greater detail below. FIG. 5B is a view along a width direction (i.e., direction hd1 extends into the plane of FIG. 5B) of the second extended structures of the patterned hard mask layer 112. FIG. 5C is a view along a lengthwise direction (i.e., direction hd2 extends into the plane of FIG. 3C) of the second extended structures of the patterned hard mask layer 112. The cross-sectional view of FIG. 5D is taken between two adjacent second extended structures of the patterned hard mask layer 112.

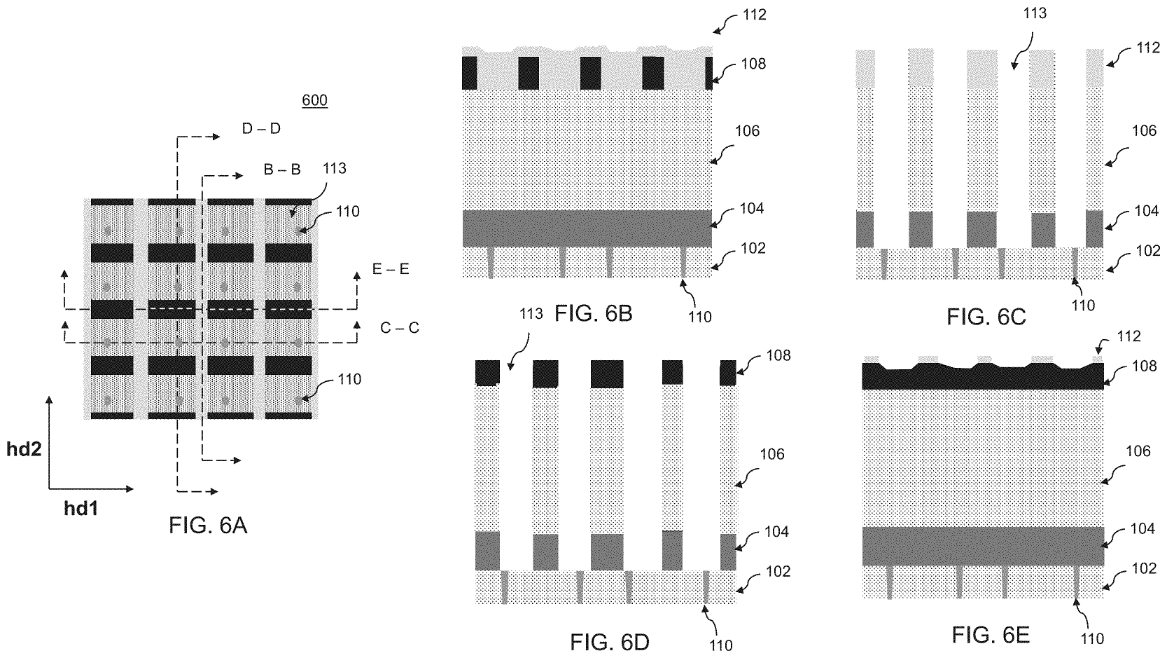

The first extended structures of the patterned upper-level etch-stop layer 108 and the second extended structures of the patterned hard mask layer 112 collectively form a bi-direction mask that may be used for patterning the dielectric layer 106L in further processing steps, as described in greater detail with reference to FIGS. 6A to 6E, below.

FIG. 6A is a plan view of a further intermediate structure 600 used in the formation of a high-density capacitor, according to various embodiments. FIGS. 6B, 6C, 6D, and 6E respectively show first, second, third, and fourth vertical cross-sectional views of the intermediate structure 600 of FIG. 6A, according to various embodiments. In this regard, the cross-section B-B of FIG. 6A is illustrated in FIG. 6B, the cross section C-C of FIG. 6A is shown in FIG. 6C, the cross-section D-D of FIG. 6A is illustrated in FIG. 6D, and the cross section E-E of FIG. 6A is shown in FIG. 6E.

The intermediate structure 600 may be formed by performing an anisotropic etch of the dielectric layer 106L using the patterned upper-level etch-stop layer 108 and the patterned hard mask layer 112 as an etch mask. In this regard, the first extended structures of the patterned upper-level etch-stop layer 108 and the second extended structures of the patterned hard mask layer 112 collectively form a bi-direction mask that may be used for patterning the dielectric layer 106L. The result of etching the dielectric layer 106L may be the formation of an array of vertical cavities 113. FIGS. 6C and 6D show the resulting cavities 113 that may be formed by allowing the anisotropic etch process to etch the dielectric layer 106L and the lower-level etch-stop layer 104L. The plurality of cavities 113 may be separated by pillar structures that include remaining dielectric portions 106 and remaining portions 104 of the lower-level etch-stop layer 104L, as shown in FIGS. 6C and 6D. The remaining first extended structures of the patterned upper-level etch-stop layer 108 are shown in FIGS. 6B, 6D, and 6E, while the remaining second extended structures of the patterned hard mask layer 112 are shown in FIGS. 6B, 6C, and 6E.

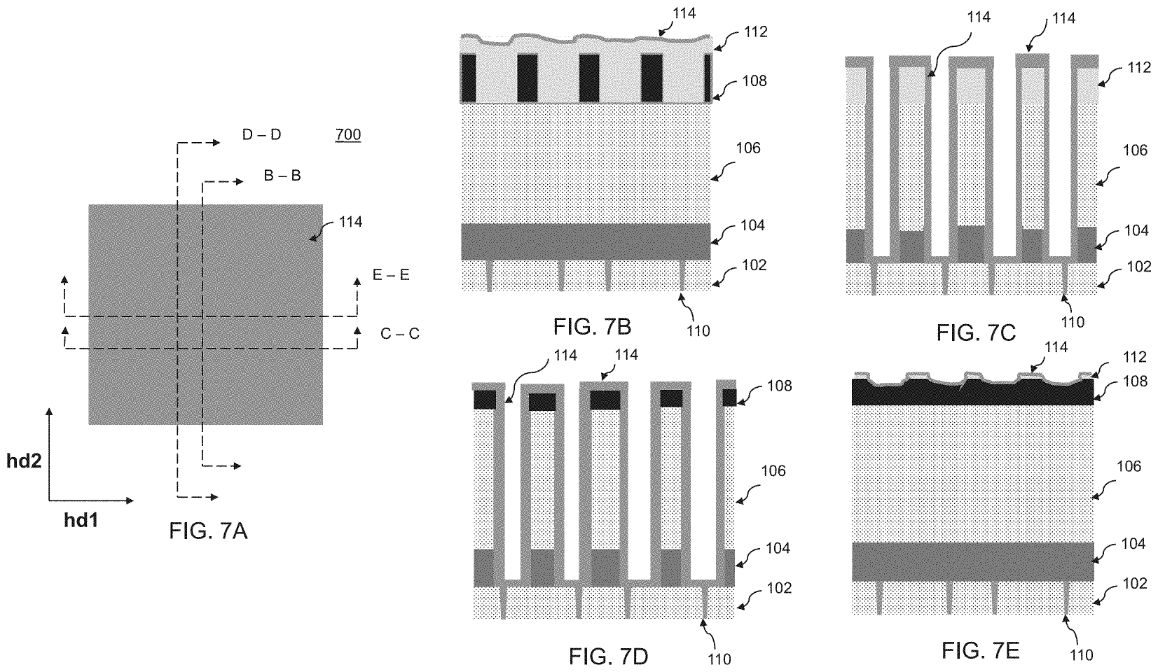

FIG. 7A is a plan view of a further intermediate structure 700 used in the formation of a high-density capacitor, according to various embodiments. FIGS. 7B, 7C, 7D, and 7E respectively show first, second, third, and fourth vertical cross-sectional views of the intermediate structure 700 of FIG. 7A, according to various embodiments. In this regard, the cross-section B-B of FIG. 7A is illustrated in FIG. 7B, the cross section C-C of FIG. 7A is shown in FIG. 7C, the cross-section D-D of FIG. 7A is illustrated in FIG. 7D, and the cross section E-E of FIG. 7A is shown in FIG. 7E.

The intermediate structure 700 may be formed by depositing a first electrically conductive material 114 over the intermediate structure 600 of FIGS. 6A to 6E. The conductive material may include a conductive metallic nitride or a conductive metallic carbide such as TiN, TaN, WN, TiC, TaC, and/or WC. Other suitable conductive materials within the contemplated scope of this disclosure may also be used. The first electrically conductive material 114 may be deposited so as to form an electrically conductive contact with the one or more conductive structures 110.

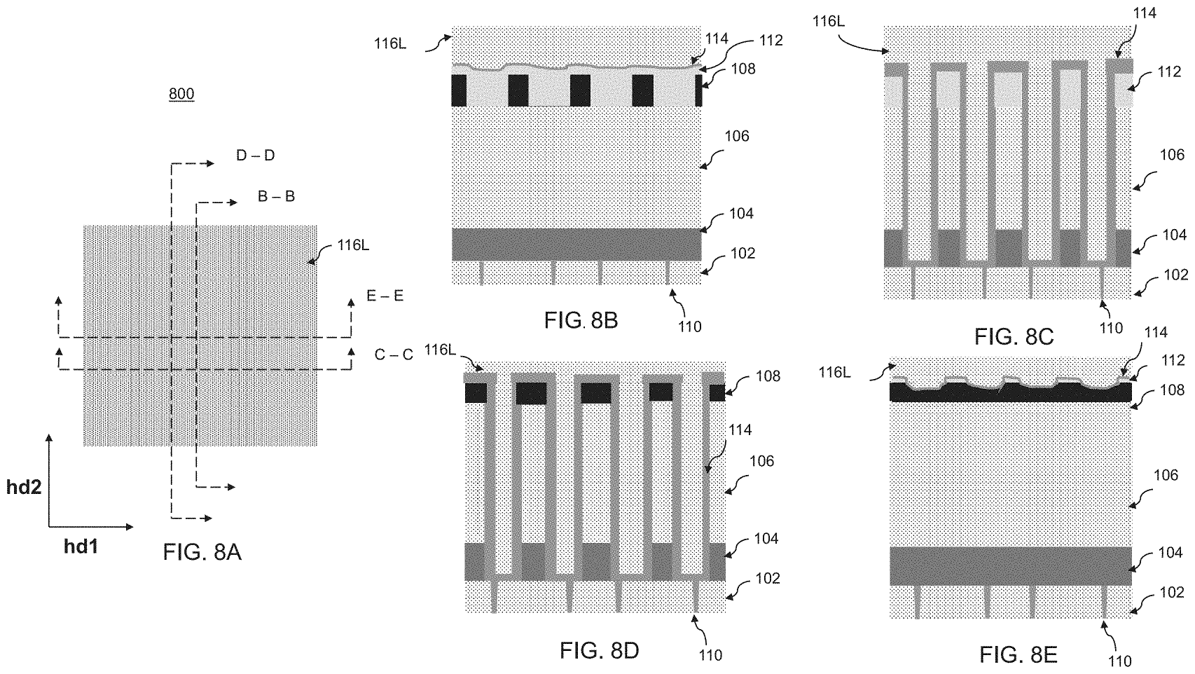

FIG. 8A is a plan view of a further intermediate structure 800 used in the formation of a high-density capacitor, according to various embodiments. FIGS. 8B, 8C, 8D, and 8E respectively show first, second, third, and fourth vertical cross-sectional views of the intermediate structure 800 of FIG. 8A, according to various embodiments. In this regard, the cross-section B-B of FIG. 8A is illustrated in FIG. 8B, the cross section C-C of FIG. 8A is shown in FIG. 8C, the cross-section D-D of FIG. 8A is illustrated in FIG. 8D, and the cross section E-E of FIG. 8A is shown in FIG. 8E.

The intermediate structure 800 may be formed by depositing a blanket layer 116L of dielectric material over the intermediate structure 700 of FIGS. 7A to 7E. The blanket layer 116L of dielectric material may include, for example, undoped silicate glass, a doped silicate glass (e.g., deposited by decomposition of TEOS), organosilicate glass, silicon oxynitride, or silicon carbide nitride. Other dielectric materials are within the contemplated scope of disclosure. The dielectric layer 116L may be deposited by a conformal deposition process (such as a chemical vapor deposition process) or a self-planarizing deposition process (such as spin coating).

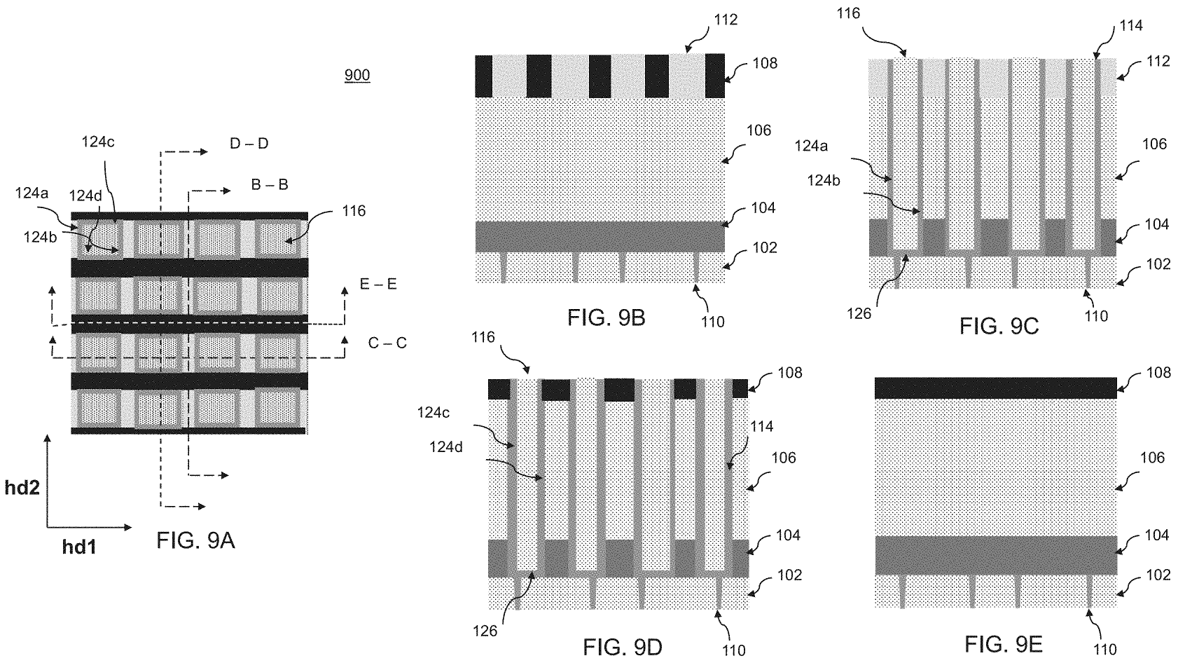

FIG. 9A is a plan view of a further intermediate structure 900 used in the formation of a high-density capacitor, according to various embodiments. FIGS. 9B, 9C, 9D, and 9E respectively show first, second, third, and fourth vertical cross-sectional views of the intermediate structure 900 of FIG. 9A, according to various embodiments. In this regard, the cross-section B-B of FIG. 9A is illustrated in FIG. 9B, the cross section C-C of FIG. 9A is shown in FIG. 9C, the cross-section D-D of FIG. 9A is illustrated in FIG. 9D, and the cross section E-E of FIG. 9A is shown in FIG. 9E.

The intermediate structure 900 may be formed by performing a planarization process on the intermediate structure 800 of FIGS. 8A to 8E. For example, chemical mechanical planarization (CMP) may be performed on the intermediate structure 800 of FIGS. 8A to 8E to thereby remove a portion of the blanket layer 116L of dielectric material to generate a planarized dielectric layer 116, as shown in FIGS. 9A, 9C, and 9D. The planarization process may also remove a top portion of the first electrically conductive material 114 and a portion of the patterned hard mask layer 112 such that dielectric layer 116, first electrically conductive material 114 and hard mask 112 may be co-planaer. In this regard, the planarization process divides the first electrically conductive material 114 into a plurality of three-dimensional structures separated from one another in a horizontal plane. As shown, for example, in FIGS. 9C and 9D, the three-dimensional structures each have four vertical walls. For example, a first vertical wall 124a and a second vertical wall 124b are shown in the second cross-sectional view of FIG. 9C. Similarly, a third vertical wall 124c and a fourth vertical wall 124d are shown in the third cross-sectional view of FIG. 9D. Each of the three-dimensional structures further includes a horizontal bottom wall 126.

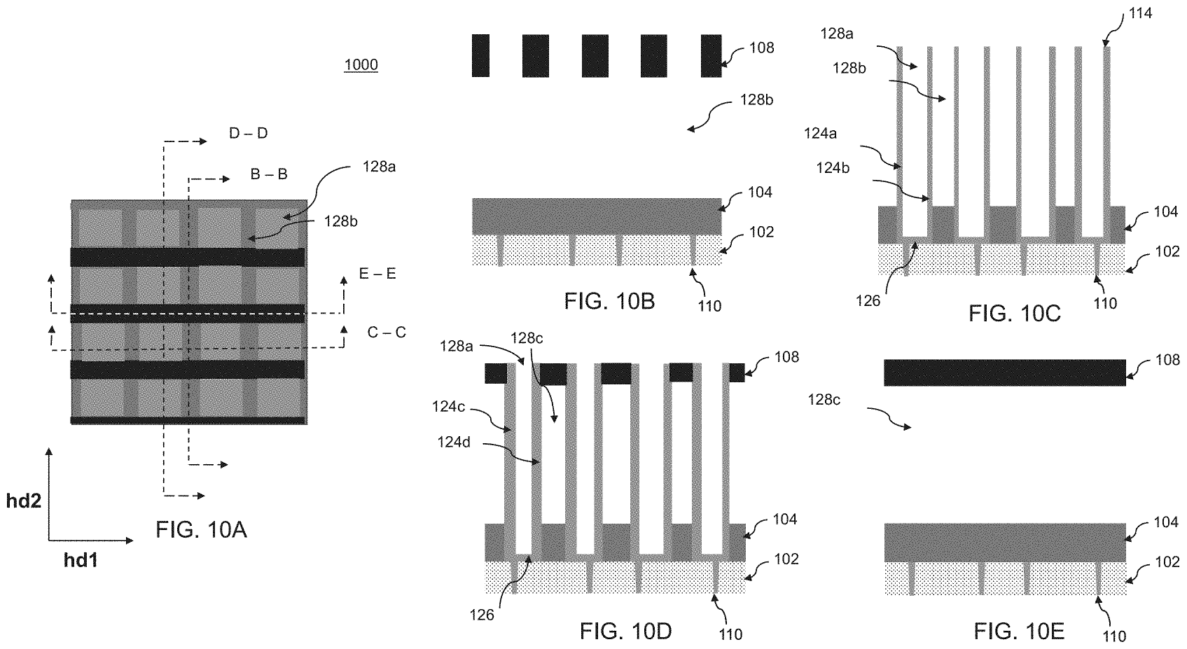

FIG. 10A is a plan view of a further intermediate structure 1000 used in the formation of a high-density capacitor, according to various embodiments. FIGS. 10B, 10C, 10D, and 10E respectively show first, second, third, and fourth vertical cross-sectional views of the intermediate structure 1000 of FIG. 10A, according to various embodiments. In this regard, the cross-section B-B of FIG. 10A is illustrated in FIG. 10B, the cross section C-C of FIG. 10A is shown in FIG. 10C, the cross-section D-D of FIG. 10A is illustrated in FIG. 10D, and the cross section E-E of FIG. 10A is shown in FIG. 10E.

The intermediate structure 1000 may be formed by performing an anisotropic etch on the intermediate structure 900 of FIGS. 9A to 9E to thereby remove the planarized dielectric layer 116 and remaining dielectric portions 106. The resulting intermediate structure 1000 is a three-dimensional mesh structure having a plurality of open regions. For example, the intermediate structure 1000 includes the plurality of three-dimensional structures, described above, that are each bounded by the first vertical wall 124a, the second vertical wall 124b, the third vertical wall 124c, and the fourth vertical wall 124d. Each of the three-dimensional structures defines a first vertical cavity 128a. As shown in FIGS. 10A, 10C, and 10D, each of the vertical cavities 128a is open at the top and closed at the bottom by the horizontal bottom wall 126.

Open spaces surrounding the three-dimensional structures form second and third types of cavities. For example, a plurality of third cavities 128c may be formed under portions of the patterned upper-level etch-stop structure 108. The third cavities 128c include open regions extending vertically (e.g., see FIG. 10D) and along a first horizontal direction (i.e., along the dashed line E-E in FIG. 10A) as shown, for example, in FIGS. 10D and 10E. Similarly, the plurality of second cavities 128b includes open regions extending vertically (e.g., see FIG. 10C) and along a second horizontal direction (i.e., along the dashed line B-B in FIG. 10A) as shown, for example, in FIGS. 10A, 10B, and 10C. Each of the plurality of first cavities 128a are separated from one another and from the plurality of second cavities 128b and the plurality of third cavities 128c (i.e., separated by the first vertical wall 124a, the second vertical wall 124b, the third vertical wall 124c, a fourth vertical wall 124d). In contrast, however, the plurality of second cavities 128b and the plurality of third cavities 128c form a connected volume.

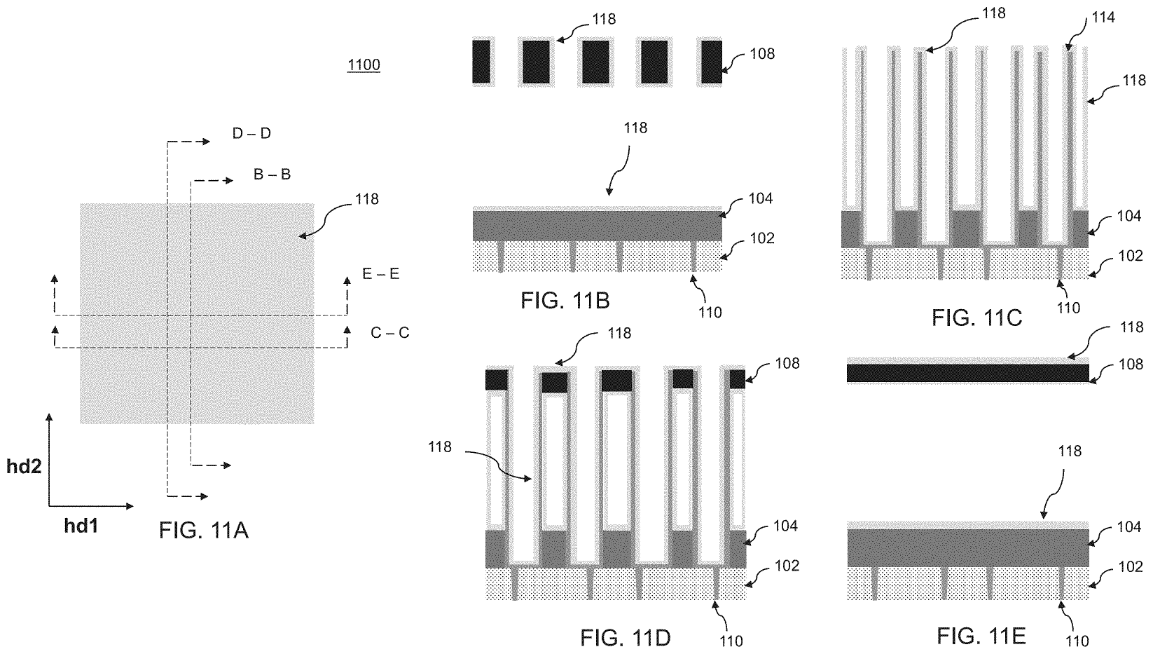

FIG. 11A is a plan view of a further intermediate structure 1100 used in the formation of a high-density capacitor, according to various embodiments. FIGS. 11B, 11C, 11D, and 11E respectively show first, second, third, and fourth vertical cross-sectional views of the intermediate structure 1100 of FIG. 11A, according to various embodiments. In this regard, the cross-section B-B of FIG. 11A is illustrated in FIG. 11B, the cross section C-C of FIG. 11A is shown in FIG. 11C, the cross-section D-D of FIG. 11A is illustrated in FIG. 11D, and the cross section E-E of FIG. 11A is shown in FIG. 11E.

The intermediate structure 1100 may be formed by deposition of a dielectric layer 118 over the intermediate structure 1000 of FIGS. 10A to 10E. According to an embodiment, the dielectric layer 118 may be conformally deposited and may include a high-k dielectric material. Examples of high-k dielectric materials include, but are not limited to, hafnium oxide (HfO₂), hafnium silicon oxide (HfSiO), hafnium tantalum oxide (HfTaO), hafnium titanium oxide (HfTiO), hafnium zirconium oxide (HfZrO), zirconium oxide, titanium oxide, aluminum oxide, and hafnium dioxide-alumina (HfO₂—Al₂O₃). Other suitable dielectric materials are within the contemplated scope of disclosure. In various embodiments, the high-k dielectric layer 118 may have a thickness in the range of 0.5-5.0 nm, such as 1-4 nm, although greater or lesser thicknesses may be used.

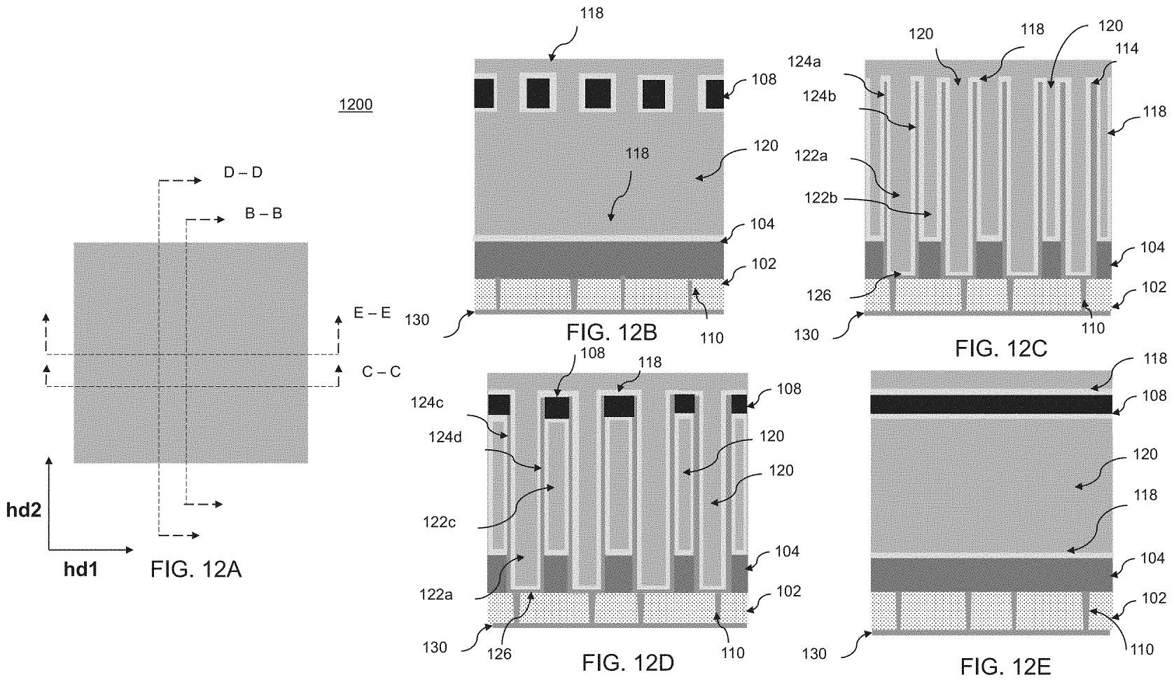

FIG. 12A is a plan view of a high-density capacitor 1200, according to various embodiments. FIGS. 12B, 12C, 12D, and 12E respectively show first, second, third, and fourth vertical cross-sectional views of the high-density capacitor 1200 of FIG. 12A, according to various embodiments. In this regard, the cross-section B-B of FIG. 12A is illustrated in FIG. 12B, the cross section C-C of FIG. 12A is shown in FIG. 12C, the cross-section D-D of FIG. 12A is illustrated in FIG. 12D, and the cross section E-E of FIG. 12A is shown in FIG. 12E.

The high-density capacitor 1200 may be formed by deposition of a second electrically conductive material 120 over the intermediate structure 1100 of FIGS. 11A to 11E. The second electrically conductive material 120 may include a metallic liner material and a metallic fill material. The metallic liner material may include a conductive metallic nitride or a conductive metallic carbide such as TiN, TaN, WN, TiC, TaC, and/or WC. The metallic fill material may include W, Cu, Al, Co, Ru, Mo, Ta, Ti, alloys thereof, and/or combinations thereof. Other suitable conductive materials within the contemplated scope of this disclosure may also be used.

The second electrically conductive material 120 may fill the plurality of first cavities 128a, the plurality of second cavities 128b, and the plurality of third cavities 128c (e.g., see FIGS. 10A to 10E). The second electrically conductive material 120 that fills the plurality of first cavities 128a, the plurality of second cavities 128b, and the plurality of third cavities may form a top electrode of the high-density capacitor 1200. As such, the top electrode forms a three-dimensional structure including a plurality of vertical portions extending in a vertical direction and horizontal portions extending horizontal directions. In this regard, second electrically conductive material 120 filling the plurality of first cavities 128a (e.g., see FIGS. 10C and 10D) may form a first plurality of vertical portions 122a of the top electrode (e.g., see FIGS. 12C and 12D), and second electrically conductive material 120 filling the plurality of second cavities 128b may form a second plurality of vertical portions 122b that are located between adjacent vertical portions of the first plurality of vertical portions 122b (e.g., see FIG. 12C).

Second electrically conductive material 120 filing the plurality of third cavities 128c may form a plurality of horizontal portions 122c of the top electrode. The plurality of horizontal portions 122c of the top electrode are interleaved within the first plurality of vertical portions 122a and the second plurality of vertical portions 122b. Further, the horizontal portions 122c extend in the first horizontal direction (i.e., along the dashed line E-E in FIG. 12A) as shown, for example, in FIGS. 12A and 12E. Similarly, he second plurality of vertical portions 122b includes portions extending vertically (e.g., see FIG. 12C) and portions extending along the second horizontal direction (i.e., along the dashed line B-B in FIG. 12A) as shown, for example, in FIGS. 12A and 12B.

The conductive material 114 that is formed on the first vertical wall 124a, the second vertical wall 124b, the third vertical wall 124c, and the fourth vertical wall 124d, of each of the plurality of three-dimensional structures, described above, forms a bottom electrode of the high-density capacitor 1200. Further, each of the three-dimensional structures of the bottom electrode envelops a respective one of the first plurality of vertical portions 122a of the top electrode (e.g., see FIG. 12C). As such, the bottom electrode envelopes some of the plurality of vertical portions of the top electrode. The bottom electrode may further include an electrically conducting horizontal structure 130 that connects all of the three-dimensional structures of the bottom electrode. In this regard, each of the horizontal bottom walls 126 are electrically connected to the one or more conductive structures 110, and the one or more conductive structures 110 are electrically connected to one another by the electrically conducting horizontal structure 130.

As shown in FIGS. 12A to 12E, the top electrode and the bottom electrode of the high-density capacitor 1200 may be separated from one another by the dielectric layer 118. The capacitance of the high-density capacitor 1200 may be proportional to a total area that separates surfaces of the top electrode from the bottom electrode. The presence of vertical wall, as well has horizontal walls, implies that the total area, and thus the total capacitance increases in proportion to the overall volume of the high-density capacitor 1200.

As described above, the high-density capacitor 1200 of FIGS. 12A to 12E includes a bottom electrode, a top electrode, and a dielectric material 118 separating the top electrode from the bottom electrode. The bottom electrode has a first electrically conducting material 114 formed as a plurality of three-dimensional structures separated from one another in a horizontal plan (as shown in FIGS. 9A to 9E), with each three-dimensional structure having four vertical walls and one horizontal bottom wall (e.g., having the first vertical wall 124a, the second vertical wall 124b, the third vertical wall 124c, the fourth vertical wall 124d, and the horizontal wall 126). The top electrode includes a second electrically conducting material 120 surrounding the bottom electrode (i.e., vertical portions 122a are formed within vertical walls of the bottom electrode, vertical portions 122b and horizontal portions 122c are formed external to vertical walls of the bottom electrode).

The high-density capacitor 1200 of FIGS. 12A to 12E further includes a plurality of support structures formed by the remaining portions of the patterned upper-level etch-stop structure 108. As shown in FIG. 12D, for example, the support structures are held by, and provide support to, the third vertical walls 124c and a fourth vertical walls 124d. Further, as shown in FIG. 12D, for example, the plurality of horizontal portions 122c of the top electrode are formed under the support structures that are formed by the remaining portions of the patterned upper-level etch-stop structure 108. Further, the support structures may be electrically insulating because they are formed by the remaining portions of the patterned upper-level etch-stop structure 108, which include a dielectric material.

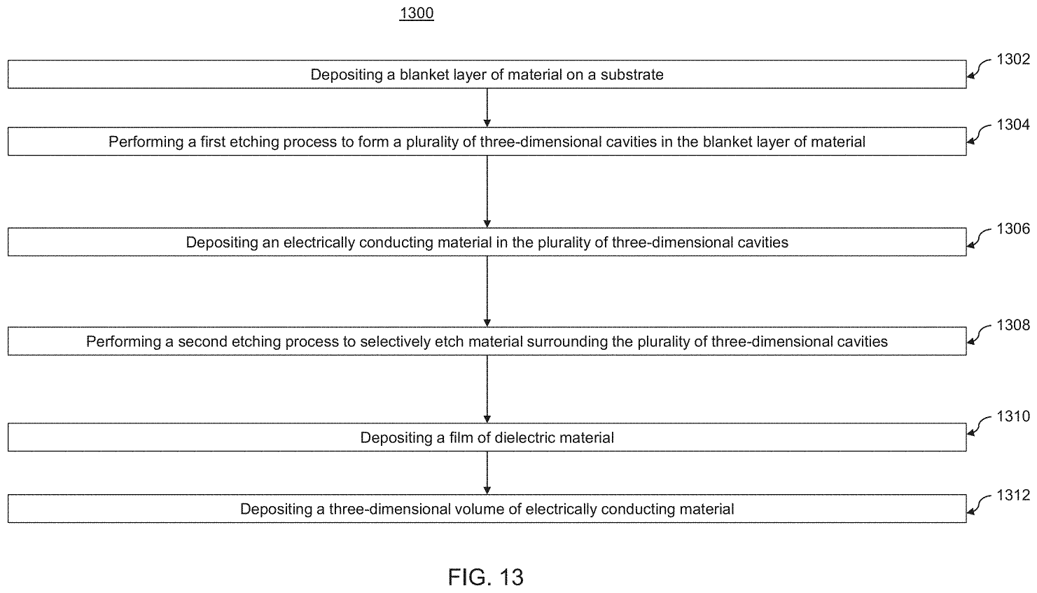

FIG. 13 is a flowchart illustrating operations of a method 1300 of fabricating a high-density capacitor, according to various embodiments. In operation 1302, the method 1300 may include depositing a blanket layer of material (104L, 106L) on a substrate 102. In operation 1304, the method 1300 may further include performing a first etching process to selectively etch the blanket layer of material (104L, 106L) to thereby form a plurality of three-dimensional cavities 113 in the blanket layer of material. In operation 1306, the method 1300 may further include depositing a first electrically conducting material 114 in the plurality of three-dimensional cavities 113 to thereby form a film of conducting material located on surfaces of the three-dimensional cavities 113.

In operation 1308, the method 1300 may include performing a second etching process to selectively etch material surrounding the plurality of three-dimensional cavities 113 to thereby form a plurality of three-dimensional structures separated from one another in a horizontal plane. Each three-dimensional structure may include vertical walls (e.g., the first vertical wall 124a, the second vertical wall 124b, the third vertical wall 124c, and the fourth vertical wall 124d) and a horizontal bottom wall 126, wherein internal surfaces of each of the three-dimensional structures include a film of the first electrically conducting material 114. In operation 1310, the method 1300 may further include depositing a film of dielectric material 118 over the film of the first electrically conducting material 114 within each of the three-dimensional structures, over external surfaces of the three-dimensional structures, and over horizontal surfaces separating the three-dimensional structures (e.g., see FIGS. 11B to 11E). In operation 1312, the method 1300 may further include depositing a three-dimensional volume of second electrically conducting material 120 to thereby surround the three-dimensional structures.

As shown in FIGS. 12B to 12E, for example, the three-dimensional volume of second electrically conducting material 120 may form a top electrode and the film of first electrically conducting material 114 within each of the three-dimensional structures may form a bottom electrode, such that the top electrode and the bottom electrode are separated by the film of dielectric material 118. In this way, that the top electrode, the bottom electrode, and the film dielectric material 118 form the high-density capacitor. With regard to the first and second etching processes, the method 1300 may further include forming an etch mask that includes a first plurality of masking structures 108 aligned with the first horizontal direction (e.g., along the dashed line E-E in FIG. 5A) and forming a second plurality of masking structures 112 aligned with the second horizontal direction (e.g., along the dashed line B-B in FIG. 5A).

The method 1300 may further include performing the first and second etching processes such that portions of the first plurality of masking structures 108 remain after performing the first and second etching processes. As such, the remaining portions of the first masking structures 108 thereby form a plurality of electrically insulating support structures aligned with a first horizontal direction (e.g., along the dashed line E-E in FIGS. 10A, 11A, and 12A). Further, the support structures may be separated from one another along the second horizontal direction (e.g., along the dashed line B-B in FIGS. 10A, 11A, and 12A) by a distance corresponding to a separation between adjacent three-dimensional structures of the bottom electrode (e.g., separation between vertical portions 122a of the top electrode).

The method 1300 may further include performing the second etching process to selectively etch material surrounding the plurality of three-dimensional cavities 113 including material below each of the support structures 108, as described above with reference to FIGS. 10A to 10E. In this regard, the plurality of first cavities 128a, the plurality of second cavities 128b, and the plurality of third cavities 128c may be generated. The method 1300 may further include depositing the three-dimensional volume of second electrically conducting material 120 to thereby surround the three-dimensional structures. As such, second electrically conducting material 120 may be formed under the support structures 108 to thereby form horizontal portions 122c of the top electrode, with the horizontal portions 122c being each located under respective support structures 108 and extending in the first horizontal direction (e.g., along the dashed line E-E in FIGS. 10A, 11A, and 12A).

The method 1300 may further including depositing the second electrically conducting material 120 within each of three-dimensional structures (e.g., within the plurality of first cavities 128a) to thereby form a first plurality of vertical portions 122a of the top electrode that are enveloped by the electrically conducting material (e.g., material 114 residing on first vertical wall 124a, the second vertical wall 124b, the third vertical wall 124c, the fourth vertical wall 124d, and by the horizontal bottom wall 126) within each of the three-dimensional structures that forms the bottom electrode. The method 1300 may further include depositing the second electrically conducting material 120 in spaces between the three-dimensional structures (i.e., within the plurality of second cavities 128b) to thereby form the second plurality of vertical portions 122b of the top electrode. The second plurality of vertical portions 122b may thereby be located between adjacent vertical portions of the first plurality of vertical portions 122a. As described above, and illustrated with reference to FIGS. 12B to 12E, the horizontal portions 122c of the top electrode are interleaved within the first plurality of vertical portions 122a and the second plurality of vertical portions 122b of vertical portions of the top electrode.

The method 1300 may further include forming the plurality of conducting structures 110 within the substrate 102 before depositing the blanket layer of material (104L, 106L) on the substrate 102. The method 1300 may further include performing the first etching process to thereby form the three-dimensional cavities 113 such that each of the three-dimensional cavities includes an exposed portion of a respective one of the conducting structures 110 (e.g., see FIGS. 6C and 6D). The method 1300 may further include depositing the first electrically conducting material 114 in the plurality of three-dimensional cavities 113 such that the first electrically conducting material 114 within each of the plurality of the three-dimensional cavities 113 forms an electrically conducting connection with the respective one of the conducting structures 110 (e.g., see FIGS. 7C and 7D). The method 1200 may further include forming an electrically conducting horizontal structure 130 (e.g., see FIGS. 12B to 12E) such that the plurality of conducting structures 110 are electrically connected to one another such that the plurality of conducting structures 110 electrically connects all of the three-dimensional structures of the bottom electrode.

With regard to the film of dielectric material 118, the method 1300 may further include depositing a high-k dielectric material over the film of first electrically conducting material 114 within each of the three-dimensional structures, over external surfaces of the three-dimensional structures (i.e., over external surfaces of the first vertical wall 124a, the second vertical wall 124b, the third vertical wall 124c, and the fourth vertical wall 124d), and over horizontal surfaces (e.g., bottom surfaces of the plurality of second cavities 128b) separating the three-dimensional structures.

Referring to all drawings and according to various embodiments of the present disclosure, a high-density capacitor is provided. The high-density capacitor 1200 (e.g., see FIGS. 12A to 12E) may include a top electrode having an second electrically conducting material 120 and forming a first three-dimensional structure. The first three-dimensional structure may include a plurality of vertical portions (122a, 122b) extending in a vertical direction and horizontal portions 122c, such that the horizontal portions 122c may be interleaved within the vertical portions (122a, 122b) and extend in a first horizontal direction (i.e., along the dashed line E-E in FIG. 12A). The high-density capacitor 1200 may further include a dielectric layer 118 formed over the top electrode, and a bottom electrode including an first electrically conducting material 114, such that the bottom electrode is separated from the top electrode by the dielectric layer 118. Further, the bottom electrode may be configured to envelope some of the plurality of vertical portions of the top electrode (i.e., the first vertical wall 124a, the second vertical wall 124b, the third vertical wall 124c, and the fourth vertical wall 124d of the bottom electrode may envelop a respective one of first plurality of vertical portions 122a of the top electrode).

The disclosed a high-density capacitor 1200 may further include a plurality of support structures (e.g., remaining portions of the patterned upper-level etch-stop structure 108) that may be aligned with the first horizontal direction (i.e., along the dashed line E-E in FIG. 12A), such that the horizontal portions 122c of the top electrode are formed under respective support structures.

Further, the high-density capacitor 1200 may be configured such that the plurality of vertical portions of the top electrode may further include the first plurality of vertical portions 122a that are enveloped by respective portions of the bottom electrode (i.e., the first vertical wall 124a, the second vertical wall 124b, the third vertical wall 124c, the fourth vertical wall 124d, and the horizontal bottom wall 126 of the bottom electrode). The plurality of vertical portions of the top electrode may further include the second plurality of vertical portions 122b that are located between adjacent vertical portions of the first plurality of vertical portions 122a (e.g., see FIG. 12C). As described above, the first electrically conducting material 114 of the bottom electrode may further include the plurality of second three-dimensional structures separated from one another in a horizontal plane, such each of the plurality of second three-dimensional structures includes four vertical walls (i.e., the first vertical wall 124a, the second vertical wall 124b, the third vertical wall 124c, the fourth vertical wall 124d) and one horizontal bottom wall (the horizontal bottom wall 126).

The high-density capacitor 1200 may further include an electrically conducting structure 130 (e.g., see FIGS. 12B to 12E) that connects all of the second three-dimensional structures of the bottom electrode. The high-density capacitor 1200 may have a capacitance that is proportional to an overall volume of the high-density capacitor. This is due to the presence of vertical as well has horizontal walls that may be configured such that the total area separating the top and bottom electrodes, and thus the total capacitance, increases in proportion to the overall volume of the high-density capacitor 1200. The dielectric layer 118 may further include a high-k dielectric material.

Various other embodiments may further include a high-density capacitor 1200 that has a bottom electrode including an first electrically conducting material 114 formed as a plurality of three-dimensional structures separated from one another in a horizontal plane, each three-dimensional structure including four vertical walls (i.e., the first vertical wall 124a, the second vertical wall 124b, the third vertical wall 124c, the fourth vertical wall 124d) and one horizontal bottom wall (the horizontal bottom wall 126). The high-density capacitor 1200 may further include a top electrode including an second electrically conducting material 120 surrounding the bottom electrode, and a dielectric material 118 separating the top electrode from the bottom electrode (e.g., see FIGS. 12B to 12E).

The high-density capacitor 1200 may further include a plurality of electrically insulating support structures (e.g., remaining portions of the patterned upper-level etch-stop structure 108) aligned with a first horizontal direction (i.e., along the dashed line E-E in FIG. 10A), such that the support structures are separated from one another along the second horizontal direction (e.g., along the dashed line B-B in FIGS. 10A, 11A, and 12A) by a distance corresponding to a separation between adjacent three-dimensional structures of the bottom electrode (e.g., a separation between vertical portions 122a of the top electrode).

The plurality of support structures may divide the top electrode into a plurality of vertical portions (122a, 122b) extending in a vertical direction and a plurality of horizontal portions 122c, such that the horizontal portions 122c are interleaved within the vertical portions (122, 122b) and extend in the first horizontal direction (e.g., along the dashed line E-E in FIGS. 10A, 11A, and 12A). Further, the horizontal portions 122c of the top electrode are formed under respective support structures (e.g., remaining portions of the patterned upper-level etch-stop structure 108). Further, each of the plurality of three-dimensional structures (e.g., the first vertical wall 124a, the second vertical wall 124b, the third vertical wall 124c, the fourth vertical wall 124d, and the horizontal bottom wall 126) of the bottom electrode envelopes a respective vertical portion 122a of the top electrode.

As described above (e.g., see FIGS. 12C and 12D) the plurality of vertical portions of the top electrode includes the first plurality of vertical portions 122a that are enveloped by respective three-dimensional structures of the bottom electrode, and the second plurality of vertical portions 122b that are located between adjacent vertical portions of the first plurality of vertical portions 122a. The bottom electrode may further include an electrically conducting structure 130 (e.g., see FIGS. 12B to 12E) that connects all of the three-dimensional structures of the bottom electrode. The high-density capacitor 1100 may include a capacitance that is proportional to a volume of the high-density capacitor. This is due to the presence of vertical as well has horizontal walls that are configured such that the total area of surfaces separating the top electrode from the bottom electrode, and thus the total capacitance, increases in proportion to the overall volume of the high-density capacitor 1200.

The above-described embodiments provide advantages over conventional capacitors. In this regard, the high-density capacitor 1200 may be formed in a BEOL process and may be incorporated with other BEOL circuit components such as TFT devices. As such, the disclosed high-density capacitor may include materials that may be processed at low temperatures and thus, may not damage previously fabricated devices (e.g., FEOL and MEOL devices). Further, the disclosed high-density capacitor 1200 may have a capacitance that is proportional to volume and thus may have a greatly increased capacitance for a given area, in contrast to conventional capacitors. Further, the disclosed method of fabrication may be easier to implement relative to methods of fabricating capacitors using a via hole process. The disclosed high-density capacitor 1200 further has a wide top electrode which may allow connections to the top electrode to be more easily established in contrast to conventional capacitors. Further, the disclosed high-density capacitor 1200 is based on a rectangular geometry that may allow a higher integration density, and thereby a higher capacitance, in contrast to capacitors that are based on a cylindrical geometry fabricated using a via hole process.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A high-density capacitor, comprising:
a top electrode comprising a second electrically conducting material and forming a first three-dimensional structure, wherein the first three-dimensional structure comprises a plurality of vertical portions and horizontal portions, wherein the horizontal portions are interleaved within the vertical portions;
a dielectric layer formed over the top electrode; and
a bottom electrode comprising a first electrically conducting material,
wherein the bottom electrode is separated from the top electrode by the dielectric layer, and
wherein the bottom electrode envelopes some of the plurality of vertical portions of the top electrode.

2. The high-density capacitor of claim 1, further comprising:
a plurality of support structures aligned with a first horizontal direction,
wherein the horizontal portions of the top electrode are formed under respective support structures.

3. The high-density capacitor of claim 1, wherein the plurality of vertical portions of the top electrode further comprises:
a first plurality of vertical portions that are enveloped by respective portions of the bottom electrode; and
a second plurality of vertical portions that are located between adjacent vertical portions of the first plurality of vertical portions.

4. The high-density capacitor of claim 1, wherein the first electrically conducting material of the bottom electrode further comprises:
a plurality of second three-dimensional structures separated from one another in a horizontal plane,
wherein each of the plurality of second three-dimensional structures comprises four vertical walls and one horizontal bottom wall.

5. The high-density capacitor of claim 4, wherein the bottom electrode further comprises an electrically conducting structure that connects all of the second three-dimensional structures of the bottom electrode.

6. The high-density capacitor of claim 1, wherein the high-density capacitor comprises a capacitance that is proportional to a volume of the high-density capacitor.

7. The high-density capacitor of claim 1, wherein the dielectric layer further comprises a high-k dielectric material.

8. A high-density capacitor, comprising:
a bottom electrode comprising a first electrically conducting material formed as a plurality of three-dimensional structures separated from one another in a horizontal plane, each three-dimensional structure comprising four vertical walls and one horizontal bottom wall;
a top electrode comprising a second electrically conducting material surrounding the bottom electrode; and
a dielectric material separating the top electrode from the bottom electrode.

9. The high-density capacitor of claim 8, further comprising:
a plurality of electrically insulating support structures aligned with a first horizontal direction,
wherein the support structures are separated from one another along a second horizontal direction by a distance corresponding to a separation between adjacent three-dimensional structures of the bottom electrode.

10. The high-density capacitor of claim 9, wherein the plurality of support structures divide the top electrode into a plurality of vertical portions extending in a vertical direction and a plurality of horizontal portions,
wherein the horizontal portions are interleaved within the vertical portions and extend in the first horizontal direction, and
wherein the horizontal portions of the top electrode are formed under respective support structures.

11. The high-density capacitor of claim 10, wherein each of the plurality of three-dimensional structures of the bottom electrode envelopes a respective vertical portion of the top electrode.

12. The high-density capacitor of claim 10, wherein the plurality of vertical portions of the top electrode comprises:
a first plurality of vertical portions that are enveloped by respective three-dimensional structures of the bottom electrode; and
a second plurality of vertical portions that are located between adjacent vertical portions of the first plurality of vertical portions.

13. The high-density capacitor of claim 8, wherein the bottom electrode further comprises an electrically conducting structure that connects all of the three-dimensional structures of the bottom electrode.

14. The high-density capacitor of claim 8, wherein the high-density capacitor comprises a capacitance that is proportional to a volume of the high-density capacitor.

15. A method of fabricating a high-density capacitor, comprising:
depositing a blanket layer of material on a substrate;
performing a first etching process to selectively etch the blanket layer of material to thereby form a plurality of three-dimensional cavities in the blanket layer of material;
depositing a first electrically conducting material in the plurality of three-dimensional cavities to thereby form a film of conducting material located on surfaces of the three-dimensional cavities;
performing a second etching process to selectively etch material surrounding the plurality of three-dimensional cavities to thereby form a plurality of three-dimensional structures separated from one another in a horizontal plane, each three-dimensional structure comprising vertical walls and a horizontal bottom wall, wherein internal surfaces of each of the three-dimensional structures comprise a film of first electrically conducting material;
depositing a film of dielectric material over the film of first electrically conducting material within each of the three-dimensional structures, over external surfaces of the three-dimensional structures, and over horizontal surfaces separating the three-dimensional structures; and
depositing a three-dimensional volume of second electrically conducting material to thereby surround the three-dimensional structures,
wherein the three-dimensional volume of second electrically conducting material forms a top electrode and the film of first electrically conducting material within each of the three-dimensional structures forms a bottom electrode, and
wherein the top electrode and the bottom electrode are separated by the film of dielectric material such that the top electrode, the bottom electrode, and the dielectric material form the high-density capacitor.

16. The method of claim 15, wherein performing the first and second etching processes further comprises:
forming an etch mask that comprises a first plurality of masking structures aligned with a first horizontal direction and forming a second plurality of masking structures aligned with a second horizontal direction; and
performing the first and second etching processes such that portions of the first plurality of masking structures remain after performing the first and second etching processes, the remaining portions of the first masking structures thereby forming a plurality of electrically insulating support structures aligned with the first horizontal direction,
wherein the support structures are separated from one another along the second horizontal direction by a distance corresponding to a separation between adjacent three-dimensional structures of the bottom electrode.

17. The method of claim 16, further comprising:
performing the second etching process to selectively etch material surrounding the plurality of three-dimensional cavities including material below each of the support structures; and
depositing the three-dimensional volume of second electrically conducting material to thereby surround the three-dimensional structures such that second electrically conducting material formed under the support structures forms horizontal portions of the top electrode, wherein the horizontal portions are each located under respective support structures and extend in the first horizontal direction.

18. The method of claim 17, wherein depositing the three-dimensional volume of second electrically conducting material further comprises:
depositing the second electrically conducting material within each of three-dimensional structures to thereby form a first plurality of vertical portions of the top electrode that are enveloped by the first electrically conducting material within each of the three-dimensional structures that forms the bottom electrode; and
depositing the second electrically conducting material in spaces between the three-dimensional structures to thereby form a second plurality of vertical portions of the top electrode that are located between adjacent vertical portions of the first plurality of vertical portions,
wherein the horizontal portions of the top electrode are interleaved within the first and second pluralities of vertical portions of the top electrode.

19. The method of claim 15, further comprising:
forming a plurality of conducting structures within the substrate before depositing the blanket layer of material on the substrate;
performing the first etching process to thereby form the three-dimensional cavities such that each of the three-dimensional cavities comprises an exposed portion of a respective one of the conducting structures; and
depositing the first electrically conducting material in the plurality of three-dimensional cavities such that the first electrically conducting material within each of the plurality of the three-dimensional cavities forms an electrically conducting connection with the respective one of the conducting structures,
wherein the plurality of conducting structures are electrically connected to one another such that the plurality of conducting structures electrically connects all of the three-dimensional structures of the bottom electrode.

20. The method of claim 15, wherein depositing the film of dielectric material further comprises depositing a high-k dielectric material over the film of first electrically conducting material within each of the three-dimensional structures, over external surfaces of the three-dimensional structures, and over horizontal surfaces separating the three-dimensional structures.
